(19) United States
(12) Patent Application Publication
(10) Pub. No.: US 2012/0217592 A1
(43) Pub. Date: Aug. 30, 2012

(54) SEMICONDUCTOR DEVICE AND METHOD FOR FORMING THE SAME

(75) Inventors: Huilong Zhu, Poughkeepsie, NY (US); Qingqing Liang, Beijing (CN)

(73) Assignee: INSTITUTE OF MICROELECTRONICS, CHINESE ACADEMY OF SCIENCES, Beijing (CN)

(21) Appl. No.: 13/119,577

(22) PCT Filed: Mar. 2, 2011
(86) PCT No.: PCT/CN11/00337

§ 371 Date: Mar. 17, 2011

(30) Foreign Application Priority Data
Jul. 1, 2010 (CN) 201010223866.0

(51) Int. Cl. H01L 29/772; H01L 21/336

(52) U.S. Cl. 257/412; 438/197; 257/E21.409; 257/E29.242

(57) ABSTRACT

It is provided a method for forming a semiconductor device, the semiconductor device comprising a PMOS device, wherein forming the PMOS device comprises: removing the sidewall spacer so as to form a void; and filling the void with an assistant layer, the assistant layer having a first compressive stress. Alternatively, a gate is formed in the PMOS device, the gate having a second compressive stress; the sidewall spacer is removed, so as to form a void; and the void is filled with an assistant layer. A semiconductor device comprising a PMOS device, the PMOS device comprising: an assistant layer, the assistant layer being formed on a semiconductor substrate, the assistant layer surrounding both a gate and a gate dielectric layer, or surrounding the gate and positioned on the gate dielectric layer, wherein the assistant layer has a first compressive stress, or the assistant layer has a first compressive stress and the gate has a second compressive stress, so as to produce a compressive stress in the channel region of the PMOS device. This helps to improve the device performance

### TECHNICAL FIELD

The present invention relates to the field of semiconductor technology and, particularly, to a semiconductor device and a method for forming the same.

### BACKGROUND ART

Generally, in a method for forming a semiconductor device, steps for forming a gate may comprise: firstly, as shown in FIG. 1, forming dummy gate stacks, each of which gate stack comprises a gate dielectric layer 12, a dummy gate 14, and a sidewall spacer 16, wherein the gate dielectric layer 12 is formed on a semiconductor substrate 10 (a P-well region 1802, an N-well region 1804, source/drain regions 20, isolation regions 22, and contact regions 24 have been formed on the semiconductor substrate 10, the isolation regions 22 isolating the NMOS device 11 and PMOS device 13), and the dummy gate 14 is formed on the gate dielectric layer 12, the sidewall spacer 16 surrounds the dummy gate 14 and is formed on the gate dielectric layer 12 (also, the sidewall spacer 16 may also surround both the dummy gate 14 and gate dielectric layer 12, which is not shown in the figure);

as shown in FIG. 2, forming a barrier layer 26 and an interlayer dielectric layer 28, wherein the barrier layer 26 is formed on the semiconductor substrate 10 and covering the dummy gate stacks, the barrier layer 26 is formed of the same material as the sidewall spacer 16, and the interlayer dielectric layer 28 is covering the barrier layer 26;

as shown in FIG. 3, planarizing the barrier layer 26 and the interlayer dielectric layer 28, so as to expose the dummy gates 14, the sidewall spacer spacers 16, and the barrier layer 26; and

as shown in FIG. 4, replacing the dummy gates 14 with gates each comprising a new gate dielectric layer 30, a work function metal layer 32, and a main metal layer 34.

In general, the material of the main metal layer 34 for both NMOS and PMOS devices is TiAl, which has an intrinsic compressive stress. It has been found in practice that such a compressive stress will create a tension stress in channel regions of both

NMOS and PMOS devices. However, a tension stress in the channel region of a PMOS device tends to deteriorate the performance of the device.

### SUMMARY OF THE INVENTION

In order to solve the above problem, the present invention provides a semiconductor device and a method for forming the same to help to improve the performance of the device.

The present invention provides a method for forming a semiconductor device, the semiconductor device comprising a PMOS device, wherein forming the PMOS device comprises the following steps: forming a gate stack, the gate stack comprising a gate dielectric layer, a gate, and a sidewall spacer, wherein the gate dielectric layer is formed on a semiconductor substrate, the gate is formed on the gate dielectric layer, and the sidewall spacer surrounds both the gate and the gate dielectric layer, or surrounds the gate and is positioned on the gate dielectric layer; removing the sidewall spacer, so as to form a void; and filling the void with an assistant layer, the assistant layer having a first compressive stress.

Optionally, the material of the assistant layer is silicon nitride.

Optionally, the step of forming the gate stack comprises: forming a dummy gate stack, the dummy gate stack comprising a gate dielectric layer, a dummy gate, and a sidewall spacer, wherein the gate dielectric layer is formed on the semiconductor substrate, the dummy gate is formed on the gate dielectric layer, the sidewall spacer surrounds both the dummy gate and the gate dielectric layer, or surrounds the dummy gate and is positioned on the gate dielectric layer; forming a barrier layer and an interlayer dielectric layer, the barrier layer being formed on the semiconductor substrate and covering the dummy gate stack, and the interlayer dielectric layer covering the barrier layer; planarizing the barrier layer and the interlayer dielectric layer, so as to expose the dummy gate, the sidewall spacer, and the barrier layer; and replacing the dummy gate with a gate material, wherein the gate material has a second compressive stress, and the second compressive stress and the first compressive stress produce a compressive stress in the channel region of the PMOS device.

Optionally, said gate material is TiAl.

Optionally, the material of the barrier layer is the same as that of the sidewall spacer, and when removing the sidewall spacer, the barrier layer is also removed.

The present invention provides a method for forming a semiconductor device, the semiconductor device comprising a PMOS device, wherein forming the PMOS device comprises the following steps: forming a gate stack, the gate stack comprising a gate dielectric layer, a gate, and a sidewall spacer, wherein the gate dielectric layer is formed on a semiconductor substrate, the gate is formed on the gate dielectric layer, the material of the gate has a second compressive stress, and the sidewall spacer surrounds both the gate and the gate dielectric layer, or surrounds the gate and is positioned on the gate dielectric layer; removing the sidewall spacer, so as to form a void; and filling the void with an assistant layer.

Optionally, the assistant layer has a first compressive stress, and the first compressive stress and the second compressive stress produce a compressive stress in the channel region of the PMOS device.

Optionally, the material of said assistant layer is silicon nitride.

Optionally, the step of forming the gate stack comprises: forming a dummy gate stack, the dummy gate stack comprising a gate dielectric layer, a dummy gate, and a sidewall spacer, wherein the gate dielectric layer is formed on the semiconductor substrate, the dummy gate is formed on the gate dielectric layer, and the sidewall spacer surrounds both the dummy gate and the gate dielectric layer, or surrounds the dummy gate and is positioned on the gate dielectric layer; forming a barrier layer and an interlayer dielectric layer, the barrier layer being formed on the semiconductor substrate and covering the dummy gate stack, and the interlayer dielectric layer covering the barrier layer; planarizing the barrier layer and the interlayer dielectric layer, so as to expose the dummy gate, the sidewall spacer, and the barrier layer; and replacing the dummy gate with a gate material.

Optionally, said gate material is TiAl.

Optionally, the material of the barrier layer is the same as that of the sidewall spacer, and when removing the sidewall spacer, the barrier layer is also removed.

The present invention provides a semiconductor device, the semiconductor device comprising a PMOS device, the PMOS device comprising: a gate dielectric layer, the gate dielectric layer being formed on a semiconductor substrate; a gate, the gate is formed on the gate dielectric layer; an assistant layer, the assistant layer is formed on the semiconductor substrate, wherein the assistant layer surrounds both the gate and the gate dielectric layer, or surrounds the gate and is positioned on the gate dielectric layer, and the assistant layer has a first compressive stress, or the assistant layer has a first compressive stress and the gate has a second compressive stress, so as to produce a compressive stress in the channel region of the PMOS device.

Optionally, the material of said assistant layer is silicon nitride.

Optionally, said gate material is TiAl.

Compared with the prior art, the technical solutions of the present invention have the following advantages.

When forming a gate, the main metal layer in the gate usually has a compressive stress (which causes the gate to have a compressive stress) taking the influence of the maturity degree of the processing procedure into account. By virtue of the sidewall spacer, the compressive stress will create a tension stress in the channel region of the device. As to a PMOS device, a tension stress in the channel region of the device tends to deteriorate the performance of the device. By removing the sidewall spacer in the PMOS device, the path via which the compressive stress is transmitted into the channel region to produce a tension stress therein is cut off, that is, the compressive stress in the gate of the PMOS device can be released. This in turn reduces the tension stress in the channel region of the PMOS device, and thus helps to improve the performance of the device.

Furthermore, after removal of the sidewall spacer in the PMOS device, a void will be created. By filling an assistant layer having a compressive stress in the void, the compressive stress may be transmitted to the channel region and produce a compressive stress in the channel region. Therefore, the performance of the device can be further improved. Moreover, by using the same material as the sidewall spacer spacer to form the assistant layer, it is advantageous that the technical solutions provided by the present invention can be compatible with existing processing procedures.

### DESCRIPTION OF THE ACCOMPANYING DRAWINGS

FIG. 1 shows a schematic structural view after forming dummy gate stacks in the prior art;

FIG. 2 shows a schematic structural view after forming an interlayer dielectric layer in the prior art;

FIG. 3 shows a schematic structural view after performing a planarizing process in the prior art;

FIG. 4 shows a schematic structural view after forming gats in the prior art;

FIG. 5 shows a schematic structural view of a semiconductor substrate in an embodiment of the method for forming a semiconductor device according to the present invention;

FIG. 6 shows a schematic structural view after forming a sacrifice layer in an embodiment of the method for forming a semiconductor device according to the present invention;

FIG. 7 shows a schematic structural view after forming a dummy gate in an embodiment of the method for forming a semiconductor device according to the present invention;

FIG. 8 shows a schematic structural view after forming a sidewall spacer in an embodiment of the method for forming a semiconductor device according to the present invention;

FIG. 9 shows a schematic structural view after forming an interlayer dielectric layer in an embodiment of the method for forming a semiconductor device according to the present invention;

FIG. 10 shows a schematic structural view after performing a planarizing process in an embodiment of the method for forming a semiconductor device according to the present invention;

FIG. 11 shows a schematic structural view after forming a gate in an embodiment of the method for forming a semiconductor device according to the present invention;

FIG. 12 shows a schematic structural view after removing the sidewall spacer spacer in an embodiment of the method for forming a semiconductor device according to the present invention; and

FIG. 13 shows a schematic structural view after depositing an assistant layer in an embodiment of the method for forming a semiconductor device according to the present invention.

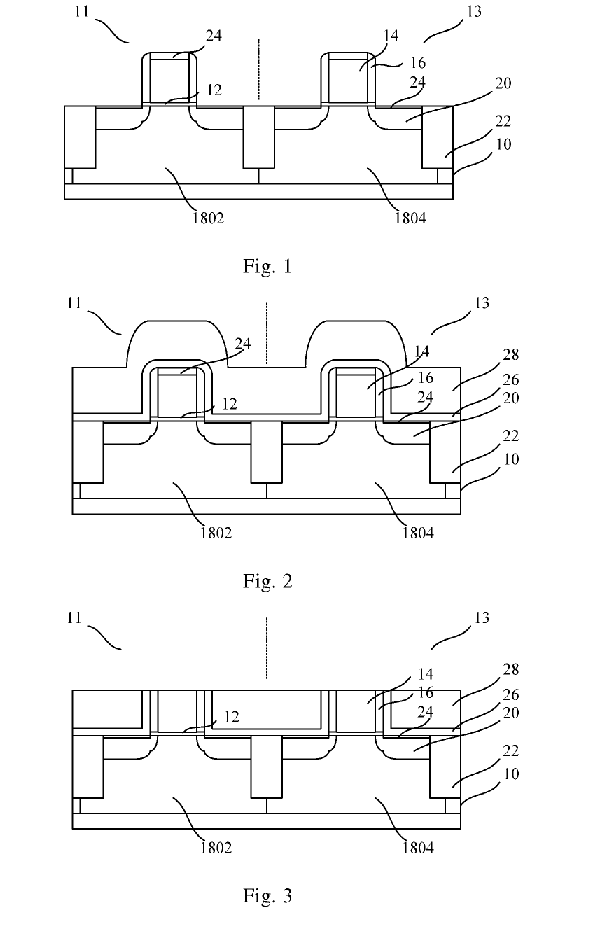

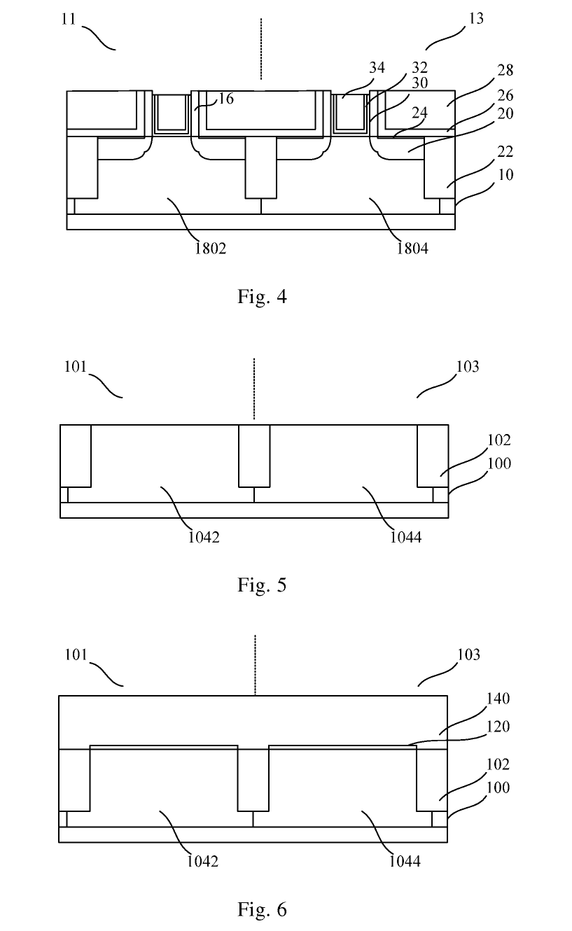

### PARTICULAR EMBODIMENTS

The following disclosure provides a number of different embodiments or examples for realizing the technical solutions provided by the present invention. Although the components and arrangements in the particular examples will be described hereinafter, they are merely taken as examples and not intended to limit the present invention.

In addition, in the present invention, reference numerals and/or letters can be repeated in the different embodiments. Such repetitions are for the purpose of simplicity and clarity and do not indicate the relationship between various embodiments and/or arrangements discussed.

The present invention provides examples of various particular processes and/or materials. However, it would be obvious that alternative applications of other processes and/or other material, which one skilled in the art would appreciate, do not depart from the protection scope claimed for the present invention. It should be emphasized that the boundaries between the various areas described in this document include necessary extensions made due to the requirements of the processes or manufacturing procedures.

The present invention provides a method for forming a semiconductor device, which comprises the following steps.

Firstly, as shown in FIG. 5, isolating regions 102 (such as STI) and well regions are formed in a wafer after the wafer is pre-cleaned, so as to form a semiconductor substrate 100 (the semiconductor substrate 100 comprising an NMOS device region 101 and a PMOS device region 103, an NMOS device being formed in the NMOS device region 101, and a PMOS device being formed in the PMOS device region 103; in the NMOS device region 101, the well region 1042 being a p-doped well, and in the PMOS device region 103, the well region 1044 being an n-doped well). The wafer may comprise a silicon wafer (in this embodiment) or other compound semiconductor, such as silicon carbide, gallium arsenide, indium arsenide, or indium phosphide. Furthermore, the wafer preferably comprises an epitaxial layer and may also comprise a silicon on insulator (SOI) structure.

Then, as shown in FIG. 6, a gate dielectric layer 120 and a sacrifice layer 140 are formed in succession on the semiconductor 100. The gate dielectric layer 120 may be formed of a material selected from hafnium based materials, such as one of HfO₂, HfSiO, HfSiON, HfTaO, HfTiO, or HfZrO, or a combination thereof. The sacrifice layer 140 may be polycrystalline silicon or amorphous silicon, and preferably polycrystalline silicon.

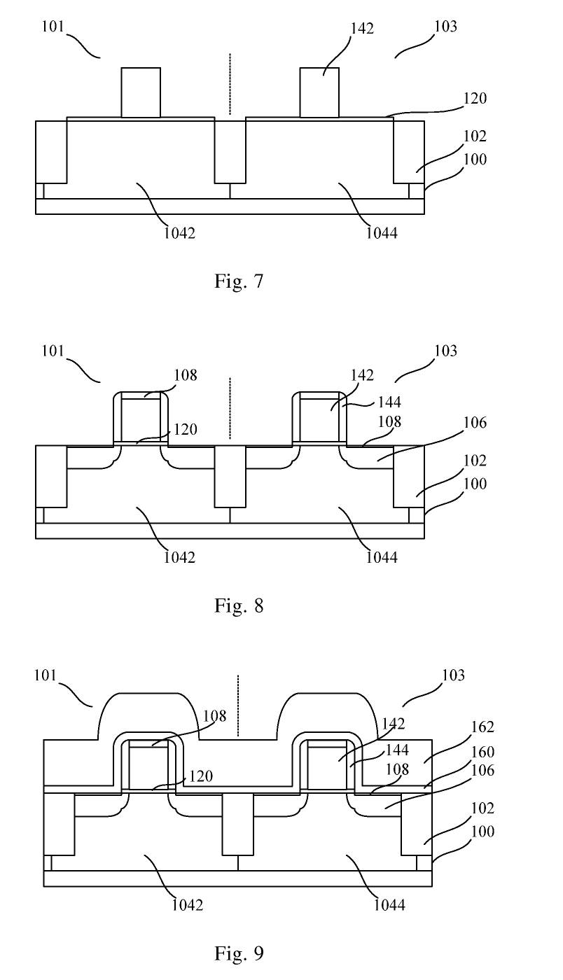

Next, as shown in FIG. 7, the sacrifice layer 140 is patterned, so as to form a dummy gate 142. The dummy gate 142 may be formed by photolithography and etching processes. Then, as shown in FIG. 8, a sidewall spacer 144 surrounding the dummy gate 142 and being on the gate dielectric layer 120 is formed, and the exposed gate dielectric layer 120 is removed to expose the semiconductor substrate 100. The sidewall spacer 144 may comprise one of silicon nitride, silicon oxide, silicon oxynitride, silicon carbide, or a combination thereof. The sidewall spacer 144 may also be a multilayer structure. In this embodiment, the material sidewall spacer 144 is preferably silicon nitride (here, an interface layer may be formed between the sidewall spacer 144 and the dummy gate 142, and the interface layer is preferably an oxide layer, which is not shown in the figure). The sidewall spacer 144 may be formed by a etch-back process. In other embodiments, it is also possible to remove the exposed the gate dielectric layer 120 after forming the dummy gate 142 and before forming the sidewall spacer 144, and by then, the sidewall spacer 144 will surround the dummy gate 142 and the gate dielectric layer 120 (in this document, the dummy gate 142, the sidewall spacer 144, and the gate dielectric layer 120 on which the dummy gate 142 is formed or both the dummy gate 142 and the sidewall spacer 144 are formed are referred to as a dummy gate stack), so as to reduce the parasitic capacitance of the device.

Next, source/drain regions 106 are formed on the semiconductor substrate 100 by using the dummy gate 142 and the sidewall spacer 144 as a mask. The source/drain regions 106 may be formed by an ion injection process or epitaxial process, which will not be described redundantly here. After that, a metal layer is formed on the dummy gate stack and the semiconductor substrate 100. Then, a heat treatment (such as RTA) is performed on the semiconductor substrate 100 having the metal layer, so as to form contact regions 108 on the dummy gate 142 and exposed portions of the semiconductor substrate 100. The material of the metal layer may be NiPt, Ni, Co, or Ti, etc., and NiPt is preferable. The temperature of the heat treatment operation can be 300°-500°, for example, 350°, 400°, or 450°. Subsequently, the unreacted metal layer is removed.

Then, as shown in FIG. 9, a barrier layer 160 and an interlayer dielectric layer 162 are formed on the semiconductor substrate that has undergone the above-described operations, with the barrier layer 160 and the interlayer dielectric layer 162 covering the dummy gate stack. The barrier layer 160 is used to prevent the doped ions in the interlayer dielectric layer 162 from entering into the semiconductor substrate 100. In the present embodiment, the material of the barrier layer 160 may be silicon nitride. In other embodiments, the barrier layer 160 may be formed of other materials. The material of the interlayer dielectric layer 162 may be undoped or doped silicon oxide glass (such as fluorosilicate glass, borosilicate glass, phosphosilicate glass, boro-phosphosilicate glass, silicon oxycarbide or carbon-silicon oxynitride, etc.) or a dielectric material with a low dielectric constant (for example, black diamond, coral, etc.), or a combination thereof.

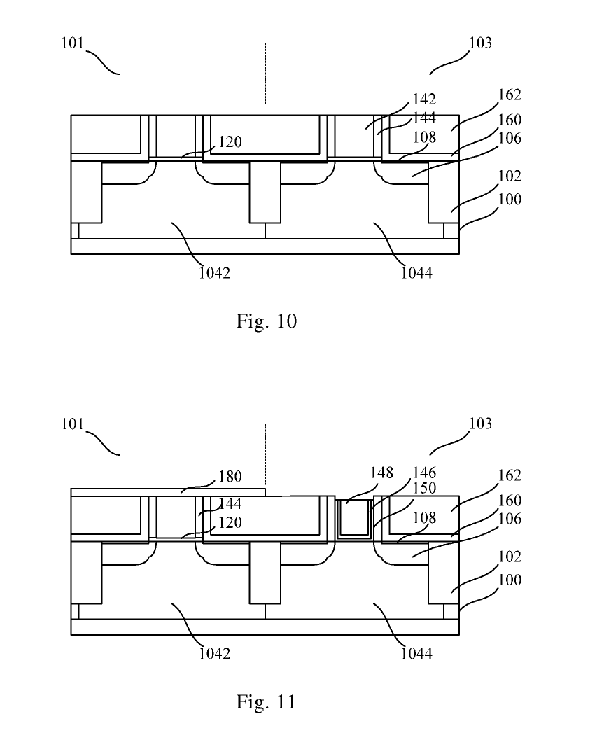

After that, as shown in FIG. 10, the barrier layer 160 and the interlayer dielectric layer 162 are planarized, so as to expose the dummy gate 142, the sidewall spacer 144 and the barrier layer 160. The planarization process may be performed by chemical mechanical polishing (CMP). Then, as shown in FIG. 11, the NMOS device region is covered with a mask 180 (for example, a silicon oxide layer). Subsequently, the dummy gate 142 in the PMOS device region is replaced with gate materials. Particularly, the dummy gate 142 is removed to form a gap, and then the gap is filled with gate materials. The gate materials in the gap may be partially etched back.

The gate material comprises a stacked work function metal layer 146 (the work function metal layer 146 is p-type, the difference between the work function of the work function metal layer 146 and the valence band of Si is less then 0.2 eV, and the material of the work function metal layer 146 can comprise any one of MoNx, TiSiN, TiCN, TaAlC, TiAlN, TaN, PtSix, Ni₃Si, Pt, Ru, Ir, Mo, HfRu, RuOx or a combination thereof) and a main metal layer 148. The main metal layer 148 can comprise any one of Al, Ti, TiAl, Ta, W or Cu, or a combination thereof, and preferably TiAl. Before forming the work function metal layer 146, the gate dielectric layer 120 exposed in the gap may be removed and a new gate dielectric layer 150 may be formed. In this case, the newly formed gate dielectric layer 150 may cover the bottom and sidewall spacers of the gap. Subsequently, the PMOS device region is covered by a mask (for example, a silicon oxide layer) and a gate may be formed in the NMOS device region. The gate of the NMOS device and the gate of the PMOS device differs in that: the work function metal layer in the gate of the NMOS device is N-type, the difference between the work function of the work function metal layer and the conduction band of Si is less than 0.2 eV, and the work function metal layer may comprise TaC, TiN, TaTbN, TaErN, TaYbN, TaSiN, HfSiN, MoSiN, RuTax, or NiTax. In this case, preferably, the main metal layer 148 in the NMOS device region and the main metal layer 148 in the PMOS device region are all TiAl. Taking the influence of the maturity degree of the process into account, TiAl usually has a compressive stress.

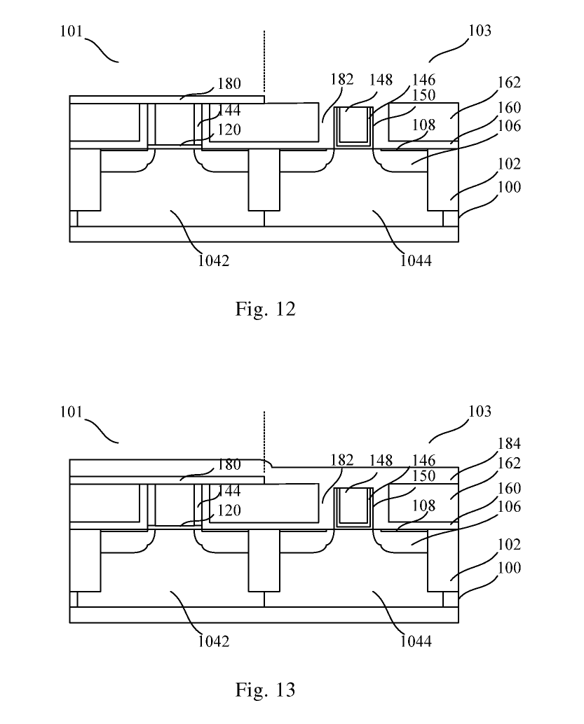

Next, the NMOS device region is covered by the mask 180 (for instance, a silicon oxide layer), and then, the gate, the sidewall spacer 144, and the barrier layer 160 in the PMOS device region are exposed. As shown in FIG. 12, the sidewall spacer 144 is removed to form a void 182. It should be pointed out that, if the material of the barrier layer 160 is the same as that of the sidewall spacer 144, when removing the sidewall spacer 144, the exposed barrier layer 160 (not covered by the interlayer dielectric layer 162) will also be removed. In other embodiments, the material of the barrier layer 160 may be different from that of the sidewall spacer 144, and then when removing the sidewall spacer 144, the exposed barrier layer 160 will remain (not shown in the figures). The removal process may be performed by a dry etching or a wet etching.

When forming the gate, taking the influence of the maturity degree of process into consideration, the main metal layer in the gate usually has a compressive stress (which in turn causes the gate to have a compressive stress). By virtue of the sidewall spacer, such a compressive stress can produce a tension stress in the channel region of the device. For a PMOS device, a tension stress in the channel region will deteriorate the performance of the device. By removing the sidewall spacer in the PMOS device, the path via which the compressive stress is transmitted into the channel region to produce a tension stress is cut off, namely, the compressive stress imposed by the gate in the PMOS device can be released. This will reduce the tension stress in the channel region of the PMOS device and helps to improve the performance of the device.

Next, as shown in FIG. 13, the void 182 is filled with an assistant layer 184. The assistant layer 184 may have a compressive stress. The material of the assistant layer 184 may be silicon nitride. By filling the void 182 with the assistant layer 184 and making the assistant layer 184 have a compressive stress, the compressive stress will be transmitted to the channel region and produce a compressive stress in the channel region, which brings a further improvement on the performance of the device. Further, by making the material of the assistant layer 184 be the same as that of the sidewall spacer 144, the technical solution according to the present invention can be compatible with the existing processing procedures. In practice, after all or partial compressive stress have been released, there may still be some residual compressive stress in the gate. In this case, it is possible for the residual compressive stress and the compressive stress imposed by the assistant layer 184 to produce a compressive stress in the channel region of the PMOS device by process control. It should be pointed out that, in the case that the assistant layer 184 does not have a stress and the gate has a compressive stress, although the compressive stress provided by the gate still generates a tensile stress in the channel region of a PMOS device, this tensile stress can be diminished by the removal of the sidewall spacer for fully or partially releasing compressive stress, and therefore the device performance can be improved.

In addition, it should be noted that, in other embodiments, even in the case that the gate does not have a compressive stress, namely, there will not be a tension stress in the channel region of the PMOS device caused by the compressive stress in the gate, by removing the sidewall spacer 144 to form a void and then filling the void with a assistant layer 184 which has a compressive stress, it is also possible to transmit the compressive stress to the channel region and produce a compressive stress in the channel region to improve the performance of the device.

Furthermore, the assistant layer 184 having a compressive stress can be formed either by various conventional processes as mentioned in the following descriptions separately, or by utilizing an etching-stop layer (usually silicon nitride in practice) formed before the formation of an Interlayer Dielectric (ILD, usually doped or undoped silicon oxide glass in practice) as said assistant layer. The disadvantage in the later case is, however, the etching-stop layer also has a compressive stress.

In the embodiments mentioned above, the gate dielectric layer 120, the sacrifice layer 140, the barrier layer 160, the interlayer dielectric layer 162, and the assistant layer 184 may be formed by Pulse Laser Deposition (PLD), Atom Layer Deposition (ALD), Plasma Enhanced Atom Layer Deposition (PEALD), or other appropriate processes.

In addition, the present invention also provides a semiconductor device, the semiconductor device comprising a PMOS device, the PMOS device comprising:

a gate dielectric layer, the gate dielectric layer being formed on a semiconductor substrate;

a gate, the gate being formed on the gate dielectric layer; and

an assistant layer, the assistant layer being formed on the semiconductor substrate, the assistant layer surrounding both the gate and the gate dielectric layer, or surrounding the gate and positioned on the gate dielectric layer, and the assistant layer has a compressive stress, or the assistant layer has a first compressive stress and the gate has a second compressive stress, so as to produce a compressive stress in the channel region of the PMOS device.

The semiconductor substrate is obtained by forming well regions and isolation regions in a wafer. The wafer may comprise a silicon wafer (in this embodiment) or other compound semiconductor, such as silicon carbide, gallium arsenide, indium arsenide, or indium phosphide. Furthermore, the wafer preferably comprises an epitaxial layer. The wafer may also comprise a silicon on insulator (SOI) structure. The material of the gate dielectric layer may be a hafnium based material, such as one or more selected from HfO₂, HfSiO, HfSiON, HfTaO, HfTiO, and HfZrO.

The gate comprises a stacked work function metal layer (for a PMOS device, the work function metal layer is P-type, the difference between the work function of the work function metal layer and the valence band of Si is less than 0.2 eV, and the material of the work function metal layer may comprise any one or more selected from MoNx, TiSiN, TiCN, TaAlC, TiAlN, TaN, PtSix, Ni₃Si, Pt, Ru, Ir, Mo, HfRu, and RuOx) and a main metal layer, and the main metal layer may comprise any one or more selected from Al, Ti, TiAl, Ta, W, and Cu, preferably TiAl. The material of the assistant layer may be silicon nitride.

The structure, material, and fabrication process of the elements of the semiconductor device in various embodiments may be the same as those described in the aforementioned embodiments of the method for forming the semiconductor device, descriptions of which are omitted here to avoid redundancy.

Moreover, the application scope of the present invention is not limited to the processes, structures, manufacturing, substance composition, means, methods, and steps of the particular embodiments described in the specification. According to the disclosure of the present invention, one skilled in the art would readily understand that for processes, structures, manufacturing, substance composition, means, methods, or steps currently existing or to be developed in future, when they perform substantially the same functions as those in the respective embodiments described in the present invention or produce substantially the same effects, they can be applied according to the teachings of the present invention, without departing from the protection scope of the present invention.

1. A method for forming a semiconductor device, the semiconductor device comprising a PMOS device, comprising the steps of:
forming a gate stack, the gate stack comprising a gate dielectric layer, a gate, and a sidewall spacer, wherein the gate dielectric layer is formed on a semiconductor substrate, the gate is formed on the gate dielectric layer, and the sidewall spacer surrounds both the gate and the gate dielectric layer, or surrounds the gate and is positioned on the gate dielectric layer;
removing the sidewall spacer, so as to form a void; and
filling the void with an assistant layer, the assistant layer having a first compressive stress.

2. The method according to claim 1, wherein the material of the assistant layer is silicon nitride.

3. The method according to claim 1, wherein the step of forming the gate stack comprises:
forming a dummy gate stack, the dummy gate stack comprising a gate dielectric layer, a dummy gate, and a sidewall spacer, wherein the gate dielectric layer is formed on the semiconductor substrate, the dummy gate is formed on the gate dielectric layer, the sidewall spacer surrounds both the dummy gate and the gate dielectric layer, or surrounds the dummy gate and is positioned on the gate dielectric layer;
forming a barrier layer and an interlayer dielectric layer, the barrier layer being formed on the semiconductor substrate and covering the dummy gate stack, and the interlayer dielectric layer covering the barrier layer;
planarizing the barrier layer and the interlayer dielectric layer, so as to expose the dummy gate, the sidewall spacer, and the barrier layer; and
replacing the dummy gate with a gate material, wherein the gate material has a second compressive stress, and the second compressive stress and the first compressive stress produce a compressive stress in the channel region of the PMOS device.

4. The method according to claim 3, wherein the gate material is TiAl.

5. The method according to claim 3, wherein the material of the barrier layer is the same as that of the sidewall spacer, and when removing the sidewall spacer, the barrier layer is also removed.

6. A method for forming a semiconductor device, the semiconductor device comprising a PMOS device, comprising the steps of:
forming a gate stack, the gate stack comprising a gate dielectric layer, a gate, and a sidewall spacer, wherein the gate dielectric layer is formed on a semiconductor substrate, the gate is formed on the gate dielectric layer, the material of the gate has a second compressive stress, and the sidewall spacer surrounds both the gate and the gate dielectric layer, or surrounds the gate and is positioned on the gate dielectric layer;
removing the sidewall spacer, so as to form a void; and
filling the void with an assistant layer.

7. The method according to claim 6, wherein the assistant layer has a first compressive stress, and the first compressive stress and the second compressive stress produce a compressive stress in the channel region of the PMOS device.

8. The method according to claim 7, wherein the material of the assistant layer is silicon nitride.

9. The method according to claim 6, wherein the step of forming the gate stack comprises:
forming a dummy gate stack, the dummy gate stack comprising a gate dielectric layer, a dummy gate, and a sidewall spacer, wherein the gate dielectric layer is formed on the semiconductor substrate, the dummy gate is formed on the gate dielectric layer, and the sidewall spacer surrounds both the dummy gate and the gate dielectric layer, or surrounds the dummy gate and is positioned on the gate dielectric layer;
forming a barrier layer and an interlayer dielectric layer, the barrier layer being formed on the semiconductor substrate and covering the dummy gate stack, and the interlayer dielectric layer covering the barrier layer;
planarizing the barrier layer and the interlayer dielectric layer, so as to expose the dummy gate, the sidewall spacer, and the barrier layer; and
replacing the dummy gate with a gate material.

10. The method according to claim 6, wherein that the gate material is TiAl.

11. The method according to claim 6, wherein the material of the barrier layer is the same as that of the sidewall spacer, and when removing the sidewall spacer, the barrier layer is also removed.

12. A semiconductor device, the semiconductor device comprising a PMOS device, the PMOS device comprising:
a gate dielectric layer, the gate dielectric layer being formed on a semiconductor substrate;
a gate, the gate is formed on the gate dielectric layer;
an assistant layer, the assistant layer is formed on the semiconductor substrate, wherein the assistant layer surrounds both the gate and the gate dielectric layer, or surrounds the gate and is positioned on the gate dielectric layer, and the assistant layer has a first compressive stress, or the assistant layer has a first compressive stress and the gate has a second compressive stress, so as to produce a compressive stress in the channel region of the PMOS device.

13. The semiconductor device according to claim 12, wherein the material of the assistant layer is silicon nitride.

14. The semiconductor device according to claim 12, wherein the gate material is TiAl.
